(19) United States
(12) Patent Application Publication
(10) Pub. No.: US 2026/0252034 A1
(43) Pub. Date: Aug. 27, 2026

(54) PROCESS FOR MANUFACTURING A SAPPHIRE TIMEPIECE ELEMENT, AND TIMEPIECE ELEMENT

(71) Applicant: ROLEX SA, Geneva (CH)

(72) Inventors: Damien Donze, Les Breuleux (CH); Benoît Junod, Peillonnex (FR); Alain Sémoroz, Lausanne (CH)

(73) Assignee: ROLEX SA, Geneva (CH)

(21) Appl. No.: 19/547,581

(22) Filed: Feb. 23, 2026

(30) Foreign Application Priority Data
Feb. 27, 2025 (EP) 25160683.6

(51) Int. Cl. G04D 3/06; G04B 39/00; G04D 3/00

(52) U.S. Cl. CPC G04D 3/065; G04B 39/006; G04D 3/0097

(57) ABSTRACT

The process for manufacturing a sapphire timepiece element includes a machining phase followed by a finishing phase. The process also includes performing a first stress-relieving heat treatment. The first stress-relieving heat treatment includes performing a holding stage at a first temperature higher than 1100° C., or even higher than 1600° C., after the machining phase.

### CROSS-REFERENCE TO RELATED APPLICATION

This application claims priority of European patent application No. EP25160683.6 filed Feb. 27, 2025, the content of which is hereby incorporated by reference herein in its entirety.

### FIELD OF THE INVENTION

The invention relates to a process for manufacturing a sapphire timepiece element. The invention also relates to a timepiece element, in particular a timepiece element obtained by such a process, in particular a timepiece case element. The invention also relates to a timepiece movement comprising such an element or a timepiece case comprising such a timepiece element. The invention lastly relates to a timepiece comprising such an element or such a timepiece movement or such a timepiece case.

### BACKGROUND ART

There are often problems with the shock resistance of sapphire timepiece glasses because, although sapphire is extremely resistant, accidental shocks can cause breakages. In addition, chips can appear around their edge, in particular when these glasses are intended to overhang a watch bezel and are therefore likely to experience shocks during everyday wear of the watch. These risks are all the more evident for recessed glasses which have very small thicknesses and/or which have cross sections comprising zones of lower mechanical strength.

Conventionally, uncolored sapphire glasses are obtained by a process comprising three standard phases:
a first phase of preparation P1, at the end of which a glass blank is obtained from a sapphire boule or slab,
a second phase of machining P2, at the end of which an unfinished glass is obtained from the glass blank,
a third phase of finishing P3, at the end of which the final glass is obtained.

As regards more specifically watch glasses, their thickness is usually sized to withstand various external stresses such as pressure and shocks. The sizing of a case is therefore dictated in particular by the sizing of the glass. More particularly, the thicker a glass is, the more resistant it is to the various external stresses, although this results in a particularly thick case. Thinning the glass, and therefore the case, thus requires redefinition of the way the glass is assembled, and a manufacturing process which makes it possible to obtain a glass sufficiently resistant to the various stresses.

Document CH718724B1 describes a watch case allowing the assembly of a thin and rigid glass made of a hard material. The watch case comprises a notch in the glass, this notch accommodating a seal intended to maintain and guarantee the water resistance of the case at the glass level. At the bottom, the notch in the glass comprises a groove which allows the insertion of a seal of dimensions suitable for the driving-in of a thin glass. This groove makes it possible to prevent the seal from rolling up on itself during the driving-in and, for esthetic reasons, from projecting above the glass after assembly.

### SUMMARY OF THE INVENTION

The aim of the invention is to provide a manufacturing process for obtaining a sapphire timepiece element, in particular a sapphire glass, which is particularly resistant to external stresses. In particular, the invention proposes a manufacturing process which improves the reliability of sapphire timepiece elements, in particular glasses. The invention also proposes an optimized assembly of a glass, in particular in the context of a particularly thin watch case.

According to a first aspect of the invention, subjects are defined by the following propositions:
1. Process for manufacturing a sapphire timepiece element (100), the process comprising a machining phase followed by a finishing phase,
   the process further comprising a first stress-relieving heat treatment step comprising a first holding stage at a first temperature higher than 1100° C. after the machining phase.
2. Manufacturing process according to proposition 1, characterized:
   in that the first temperature is higher than 1600° C., and/or
   in that the first temperature is lower than 2000° C. or lower than 1950° C. or lower than 1800° C. or lower than 1750° C.
3. Manufacturing process according to one of propositions 1 and 2, characterized in that the first stress-relieving heat treatment step takes place between the machining and finishing phases.
4. Manufacturing process according to one of propositions 1 and 2, characterized in that the first stress-relieving heat treatment step takes place between two successive polishing steps of the finishing phase.
5. Manufacturing process according to one of propositions 1 to 4, characterized in that the manufacturing process comprises a second stress-relieving heat treatment step, comprising a holding stage at a temperature of between 1000° C. and 1200° C., in particular at a temperature of approximately 1050° C.
6. Manufacturing process according to proposition 5, characterized in that the second stress-relieving heat treatment step takes place between the machining and finishing phases.
7. Manufacturing process according to one of propositions 1 to 6, characterized in that the manufacturing process comprises a third stress-relieving heat treatment step, comprising a holding stage at a temperature of between 1000° C. and 1200° C., in particular at a temperature of approximately 1050° C., which takes place between two successive machining steps of the machining phase.
8. Manufacturing process according to one of propositions 1 to 7, characterized in that the manufacturing process comprises:
   a preparation phase prior to the machining phase, and
   a fourth stress-relieving heat treatment step, comprising a holding stage at a temperature of between 1000° C. and 1200° C., in particular at a temperature of approximately 1050° C., which takes place between the preparation phase and the machining phase.
9. Manufacturing process according to one of propositions 1 to 8, characterized in that the first holding stage at the first temperature has a duration of between 2 hours and 15 hours, typically 5 hours.
10. Manufacturing process according to one of propositions 1 to 9, characterized in that one, several or all of the second, third and fourth steps comprises or comprise a holding stage at a temperature of approximately 1050° C., the holding stage having a duration of between 2 hours and 15 hours, typically 5 hours.
11. Manufacturing process according to one of propositions 1 to 10, characterized in that one or several or all of the first, second, third and fourth steps are carried out under a controlled atmosphere, in particular:
   under vacuum, or
   under a neutral or inert gas, or
   under a reducing or deoxidizing atmosphere, using for example a reducing gas such as an H2 -N2 mixture, or using for example a neutral or inert gas combined with graphite heating elements which will produce carbon monoxide, or
   under an oxidizing atmosphere, for example under air.
12. Manufacturing process according to one of propositions 1 to 11, characterized in that the timepiece element (100) is a glass and the machining phase comprises making a recess in the glass and/or in that the timepiece element (100) is made of colorless sapphire or uncolored sapphire.
13. Manufacturing process according to one of propositions 1 to 11, characterized in that the timepiece element is an external-parts element or timepiece-movement element, in particular:
   a glass, notably intended to be attached to a middle or back, or
   a back, or
   a crown, or
   a bezel, or
   a bezel disk, or
   a middle, or
   a middle including a glass, i.e. the middle forms a glass or the middle is formed in one piece with the glass, or
   an indicator disk, in particular a calendar disk.
14. Sapphire timepiece element (100), in particular made of colorless sapphire or uncolored sapphire, obtained by implementing the manufacturing process according to one of propositions 1 to 13.
15. Timepiece case (400) comprising a sapphire timepiece element (100) according to proposition 14.

16. Timepiece movement (150) comprising a sapphire timepiece element (100) according to proposition 14.
17. Timepiece (300), in particular wristwatch, comprising:
   a sapphire timepiece element (100) according to proposition 14, and/or
   a timepiece case (400) according to proposition 15, and/or
   a timepiece movement (150) according to proposition 16.

According to a second aspect of the invention, subjects are defined by the following propositions:
18. Element (100) of a case (400) for a timepiece (300) of the glass type, the element comprising:
   an outer face (100a) intended to be in contact with the external environment,
   an inner face (100b) intended to be in contact with the inner volume of the timepiece case, and
   a lateral edge (100d) connecting the outer face and the inner face,
   the lateral edge (100d) comprising a slot (1c) and the inner face comprising a recess (1d) such that the lateral edge (100d) comprises a skirt (1f).
19. Element according to proposition 18, characterized in that the element (100) is made of:
   transparent ceramic, in particular transparent polycrystalline ceramic or transparent monocrystalline ceramic, or
   glass, in particular tempered glass, or
   sapphire.
20. Element according to one of propositions 18 and 19, characterized in that the lateral edge (100d) comprises:
   on a first side of the slot (1c), a first portion (1b) intended to cooperate with a seal (2), and
   on a second side of the slot (1c), a second portion (1a), of greater size, in particular greater diameter, than the first portion (1b).
21. Element according to one of propositions 18 to 20, characterized in that the element is sized to withstand a pressure of at least 10 bar applied to the outer face (100a).
22. Element according to one of propositions 18 to 21, characterized in that a first thickness (e1) measured between the outer face and the bottom of the recess is comprised between 1 mm and 1.5 mm, typically approximately 1.3 mm.
23. Element according to one of propositions 18 to 22, characterized in that a second thickness (e2) measured between the bottom of the slot and a sidewall of the recess is comprised between 0.35 mm and 0.5 mm.
24. Element according to one of propositions 18 to 23, characterized in that a third thickness (e3) of the skirt is comprised between 0.4 mm and 0.6 mm.
25. Element according to proposition 24 and according to proposition 22, characterized in that the ratio of the third thickness (e3) to the first thickness (e1) is less than 1, or comprised between 0.3 and 0.5, typically 0.35 or 0.42.
26. Element according to one of propositions 18 to 25, characterized in that a depth (e4) of the recess (1d) is comprised between 0.2 mm and 0.6 mm.
27. Element according to one of propositions 18 to 26 and according to proposition 20, characterized in that a thickness (e5) of the first portion (1b) is comprised between 0.3 mm and 0.4 mm, typically 0.38 mm.
28. Element according to proposition 26 and according to proposition 27, characterized in that the ratio of the thickness (e5) to the depth (e4) of the recess (1d) is less than 1, or comprised between 0.7 and 0.8, typically 0.76.
29. Element according to one of propositions 18 to 28, characterized in that it comprises a fillet (1g) between the bottom of the recess and the skirt, the fillet (1g) having a radius of between 0.1 mm and 0.7 mm, typically 0.3 mm or 0.6 mm.
30. Element according to one of propositions 18 to 29, characterized in that the element is obtained by the process according to one of propositions 1 to 13.
31. Timepiece case (400) comprising a timepiece element (100) according to one of propositions 18 to 30.
32. Timepiece case (400) according to proposition 31, characterized in that it comprises a bezel (4) and a seal (2) arranged between the bezel and the timepiece element (100).
33. Timepiece case (400) according to proposition 31, characterized in that it comprises a back and a seal (2) arranged between the back and the element (100).
34. Timepiece case (400) according to one of propositions 31 to 33, characterized in that the seal (2) is made of:
   nylon or polyamide, such as polyamide 6 or 6.6 or a Zytel® or a Grilamid®, or
   thermoplastic elastomer or thermoplastic elastomer copolyester such as Hytrel®.
35. Timepiece case (400) according to one of propositions 31 to 34, characterized in that it comprises a middle (3) and in that the slot (1c) cooperates with a projection (2a) of the seal (2) so as to anchor the timepiece element (100), in particular to the bezel (4) and/or to the middle (3) and/or back.
36. Timepiece case (400) according to one of propositions 31 to 35, characterized in that it comprises a middle (3) having an aperture size (d2), in particular an aperture diameter (d2), and in that the size of the recess bottom, in particular the diameter (d1) of the recess bottom, is greater than or equal to the aperture size (d2), in particular the aperture diameter (d2).
37. Timepiece (300), in particular wristwatch, comprising:
   a timepiece element (100) according to one of propositions 18 to 30, and/or
   a timepiece case (400) according to one of propositions 31 to 36.

### BRIEF DESCRIPTION OF THE DRAWINGS

The figures show, by way of example, three embodiments of a timepiece according to the invention.

FIG. 1 illustrates a first embodiment of a timepiece according to the invention.

FIG. 2 is a graph illustrating effects of the manufacturing process according to the invention on the characteristics of a sapphire glass according to the first embodiment.

FIG. 3 illustrates a second embodiment of a timepiece according to the invention.

FIG. 4 is a graph illustrating effects of the manufacturing process according to the invention on the characteristics of a sapphire glass according to the second embodiment.

FIG. 5 is a flow diagram of a first embodiment of the manufacturing process according to the invention.

FIG. 6 is a flow diagram of a second embodiment of the manufacturing process according to the invention.

FIG. 7 is a flow diagram of a third embodiment of the manufacturing process according to the invention.

FIG. 8 is a flow diagram of a fourth embodiment of the manufacturing process according to the invention.

FIG. 9 is a flow diagram of a fifth embodiment of the manufacturing process according to the invention.

FIG. 10 is a view of a detail of the second embodiment of a timepiece according to the invention.

FIG. 11 is a view of a detail of a third embodiment of a timepiece according to the invention.

### DETAILED DESCRIPTION OF PARTICULAR EMBODIMENTS

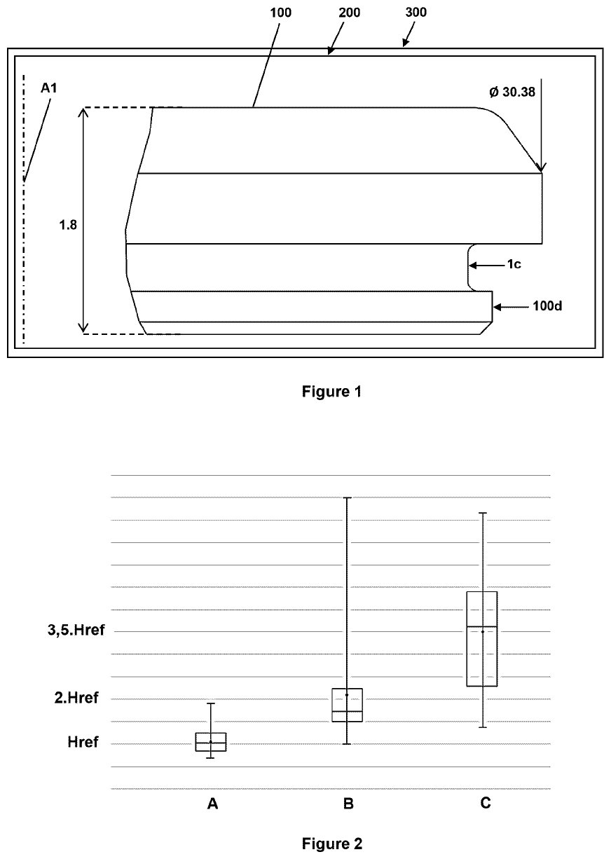

Three embodiments of a timepiece 300 according to the invention are described below with reference to FIGS. 1, 3, 10 and 11. The timepiece is for example a watch, in particular a wristwatch. The timepiece comprises a timepiece movement. The timepiece movement 200 may be:
a mechanical movement, in particular an automatic movement, or
an electronic movement, or
a hybrid movement.

The timepiece 300 also comprises a case 400 intended to receive the timepiece movement 200 and to protect it from the external environment.

The case 400 comprises:
a middle 3,
a glass 100,
a seal 2, and
possibly, a bezel 4, for example a bezel or a bezel portion which is fixed in place relative to the middle 3,
possibly, a back attached to the middle or made in one piece with the middle.

The timepiece 300, in particular the case 400 or the timepiece movement 200, comprises a transparent timepiece element 100, in particular:
the glass, notably intended to be attached to the middle or back, or
the back, or
a crown, or
a bezel, or
a bezel disk, or
a middle, or
a middle including a glass, i.e. the middle forms a glass or the middle is formed in one piece with the glass, or
an indicator disk, in particular a calendar disk.

The timepiece element 100 can therefore be an external-parts element or a timepiece-movement element.

The timepiece element 100 may be made of:
transparent ceramic, in particular transparent polycrystalline ceramic or transparent monocrystalline ceramic such as YAG for example, or
glass, in particular tempered glass, or
sapphire.

The timepiece element 100 comprises an axis A1 extending parallel to the thickness (i.e. the smallest dimension) of the timepiece element. The axis A1 is preferably centered on the timepiece element 100.

According to the various embodiments, the timepiece element 100 is preferably made of sapphire and preferably obtained by implementing one embodiment of a manufacturing process comprising:
a machining phase, then
a finishing phase,
   the process for manufacturing the timepiece element 100 further comprising a first stress-relieving heat treatment step at a first temperature higher than 1100° C. after the machining phase.

The first temperature is preferably:
higher than 1600° C., and/or
lower than 2000° C. or lower than 1950° C. or lower than 1800° C. or lower than 1750° C.

The first stress-relieving heat treatment step can take place:
between the machining and finishing phases, or
between two successive polishing steps of the finishing phase.

Experimental studies conducted by the Applicant have in particular shown that the stress-relieving heat treatment step makes it possible to obtain elements, in particular glasses, which are better able to withstand accidental shocks, in particular being dropped from a height of one meter or more, which can for example inadvertently occur when the wearer takes the watch off of their wrist. In particular, the studies conducted by the Applicant have shown that the stress-relieving heat treatment step makes it possible to increase the height from which the watch can be dropped before breakage occurs. In these studies, a piece of equipment used is a Bélier striker, as described in the NIHS 91-10 or ISO 1413 standard. Two distinct series of tests were carried out on watch cases provided with sapphire glasses of different geometries. In particular, the equipment used had the particular feature of being provided with an aluminum (and not hardwood) shoe, so that the glass could break but the shoe could not. The cases were also all oriented in the same way, such that the shoe first of all struck the edge or the perimeter of the glass.

A first series of tests concerned different configurations of a flat circular glass given a thickness of 1.8 mm and a diameter of 30.38 mm (shown in FIG. 1) and having a type A crystallographic orientation obtained by the Verneuil growth process. The glass further comprises an annular groove or slot 1c in order to allow the glass to be assembled on the middle, via a seal intended to be accommodated in this groove.

The different configurations comprise:
a reference first batch A of 100 glasses obtained by a manufacturing process including a stress-relieving heat treatment TT1 at a temperature of 1100° C., carried out between a second phase of machining P2 and a third phase of finishing P3,
a second batch B of 100 glasses that have undergone an additional stress-relieving heat treatment at 1650° C. carried out during a third phase of finishing (in addition to a stress-relieving heat treatment TT1 at a temperature of 1100° C., carried out between the second phase of machining P2 and the third phase of finishing P3), and
a third batch C of 100 glasses that have undergone a single stress-relieving heat treatment at 1920° C. carried out between the second phase of machining P2 and the third phase of finishing P3 (instead of the stress-relieving heat treatment at a temperature of 1100° C., carried out between the second phase of machining P2 and the third phase of finishing P3).

In practice:
for the second batch B, the stress-relieving heat treatment is carried out under air, and the holding stage at 1650° C. lasts for 5 hours,
for the third batch C, the stress-relieving heat treatment is carried out under a neutral or inert gas, in particular under an argon atmosphere, and the holding stage at 1920° C. also lasts for 5 hours.

FIG. 2 reveals the gains brought about by the heat treatments carried out on batches B and C, the heat treatment that was carried out at a higher temperature (instead of the stress-relieving heat treatment TT1 beforehand at a temperature of 1100° C.), i.e. that of the third batch C, being the most favorable, with a mean breakage height approximately 3 and a half times greater than a mean reference height Href measured for batch A. Second batch B also gives good results with a mean breakage height of around 2 times the mean reference height Href. On the graph, the ends of the vertical segments represent the extreme values obtained. The box-and-whisker plots (or Tukey box plots) therefore represent:
the extreme values (ends of the vertical segments),
the median values (horizontal segments in the rectangles),
the first quartiles (bottom sides of the rectangles), and
the third quartiles (top sides of the rectangles) of the glasses tested.

The dot in each rectangle represents the mean value.

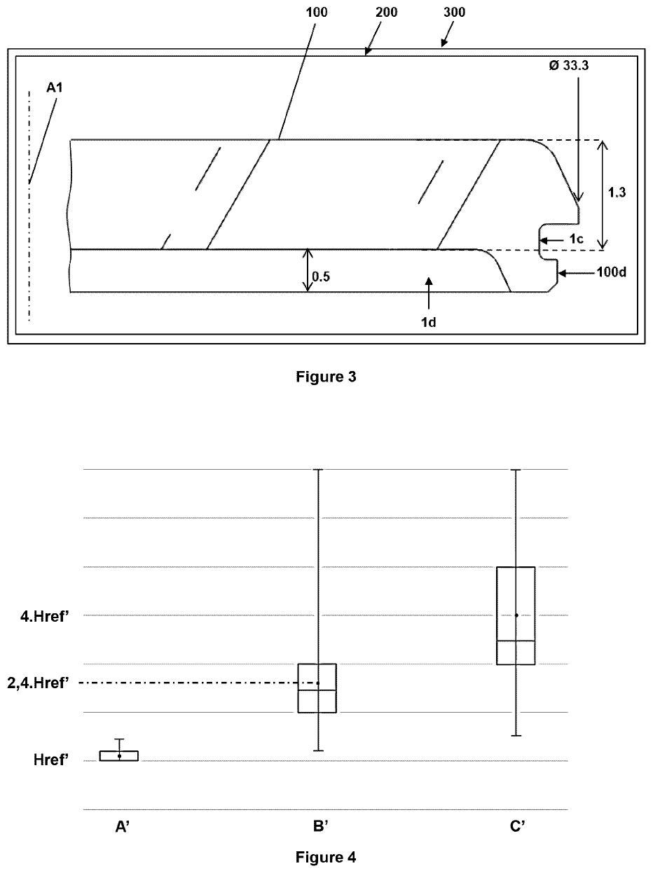

The second series of tests concerns different configurations of a recessed glass, i.e. a glass provided with a recess 1d (as shown in FIG. 3), which is given a thickness of 1.3 mm at its center and a diameter of 33.3 mm. The glass has a type A crystallographic orientation obtained by the Verneuil growth process. The glass further comprises an annular groove or a slot 1c, formed in its perimeter 100d or lateral edge 100d, in order to allow the glass to be assembled on the middle via a seal intended to be accommodated in this same groove or slot.

The different configurations comprise:
a reference first batch A′ of 20 glasses obtained by a manufacturing process including a stress-relieving heat treatment TT1 at a temperature of 1100° C., carried out between the second phase of machining P2 and the third phase of finishing P3,
a second batch B′ of 20 glasses that have undergone an additional stress-relieving heat treatment at 1600° C. during the third phase of finishing (in addition to the stress-relieving heat treatment TT1 at a temperature of 1100° C., carried out between the second phase of machining P2 and the third phase of finishing P3), and
a third batch C′ of 20 glasses that have undergone an additional stress-relieving heat treatment at 1750° C. carried out during the third phase of finishing (in addition to the stress-relieving heat treatment TT1 at a temperature of 1100° C., carried out between the second phase of machining P2 and the third phase of finishing P3).

This second series of tests again shows that the heat treatment carried out at a higher temperature, i.e. that of third batch C′, is the most favorable, with a mean breakage height of around 4 times the mean breakage height Href′ of reference first batch A′ as illustrated in FIG. 4. Second batch B′ also gives good results with a mean breakage height of around 2.4 times the mean reference height Href′.

In this case, too, these two series of tests show the advantage of a stress-relieving heat treatment carried out at the end of the procedure, at a very high temperature, whether it is in addition to or not in addition to a stress-relieving heat treatment carried out at a temperature of 1100° C. or lower than 1100° C.

The process for manufacturing the timepiece element 100 of the glass type comprises three phases:
a first phase of preparation P1, at the end of which a glass blank is obtained from a sapphire boule or slab,
a second phase of machining P2, at the end of which an unfinished glass is obtained from the glass blank,
a third phase of finishing P3, at the end of which the final glass is obtained.

The phases of machining P2 and finishing P3 differ in that the machining phase is a material removal phase made up of material removal steps for at least partially obtaining the geometry of the timepiece element 100, and in that the finishing phase is a finishing phase made up of finishing steps for at least partially obtaining the surface finish of the timepiece element 100.

Preferably, the roughness Ra of the visible surface of the timepiece element 100 through which other elements of a timepiece provided with the timepiece element 100, in particular the glass 100, are visible is:
greater than 0.2 um before the finishing phase (and thus before the glass is mounted on the timepiece), and
less than 0.2 um after the finishing phase (and thus in particular measurable on the timepiece).

As an alternative or in addition, the transmission of light through the visible surface of the timepiece element 100, in particular the glass 100, before the finishing phase (and therefore before the glass is mounted on the timepiece) is comprised between 40% and 50%, whereas it is greater than 80% after the finishing phase.

Irrespective of the embodiment or the variant, the process comprises a first stress-relieving heat treatment step TT1′. The first stress-relieving heat treatment step TT1′:
is carried out after the second phase of machining P2, and
comprises a temperature holding stage (during which the temperature is stable and) higher than 1100° C., or even much higher than 1100° C., typically of between 1600° C. and 2000° C.

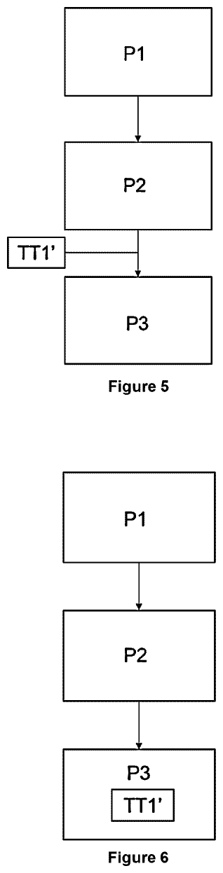

As illustrated in FIG. 5, in a first embodiment of the process, this step can be carried out between the second phase of machining P2 and the third phase of finishing P3.

As illustrated in FIG. 6, in a second embodiment of the process, this step TT1′ can be carried out during the third phase of finishing P3, i.e. between two steps involved in the third phase of finishing.

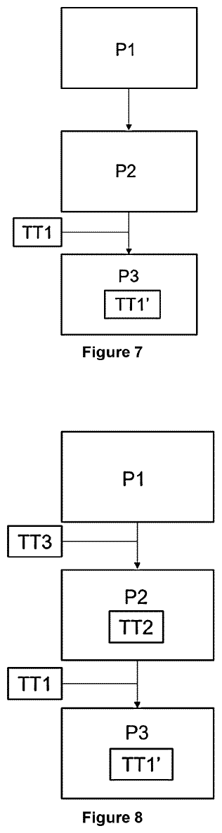

According to one particular variant of this second embodiment illustrated in FIG. 7, step TT1′ can be carried out in addition to a second stress-relieving heat treatment step TT1 at a temperature approximately equal to 1050° C. or at a temperature of between 1000° C. and 2000° C. and which can be carried out between the second phase of machining P2 and the third phase of finishing P3.

According to another particular variant of this second embodiment illustrated in FIG. 8, the process comprises two other stress-relieving heat treatment steps beforehand, for example both comprising a temperature holding stage at approximately 1050° C., in particular between 1000° C. and 1200° C. It can involve:
a heat treatment step TT3 carried out between a first phase of preparation P1 and the second phase of machining P2, and
a heat treatment step TT2 carried out during the second phase of machining P2.

The first stress-relieving heat treatment step TT1′ can be carried out:
at a temperature higher than 1100° C., or even much higher than 1100° C., in particular higher than 1600° C., and/or
at a temperature lower than 2000° C. or lower than 1950° C. or lower than 1800° C. or lower than 1750° C.

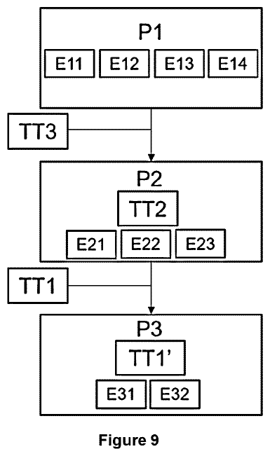

As illustrated in FIG. 9, irrespective of the embodiment or the variant, the first phase of preparation P1 can comprise in particular:
a first step E11 of providing a sapphire blank, in particular a sapphire boule (obtained in particular by the Verneuil process) or a sapphire slab (in particular obtained by the EFG process).
a second step E12 of sawing the blank, in particular the boule or the slab, so as to obtain slices which prefigure glass blanks.
third and fourth steps E13, E14, of lapping and rounding, respectively, for obtaining glass blanks which have planar and/or parallel top and bottom surfaces and form cylindrical blanks.

The heat treatment step TT3 comprises, for example, a temperature holding stage at approximately 1050° C., in particular between 1000° C. and 1200° C., and can possibly occur at the end of the first phase P1.

Irrespective of the embodiment or the variant, the second phase of machining P2 may then comprise various steps for obtaining the final geometry of the glass. This second phase P2 comprises in particular a step E21 of truing or grinding, which forms the perimeter or the lateral edge 100d of the glass. This step E21 can in particular comprise a substep or various substeps for obtaining the annular groove or the slot 1c, and the recess 1d in the specific instance of a process for manufacturing a recessed glass. Another step E22 makes it possible to form the bevels or the angles of the glass. A step E23 of felting and patinating the recess can also be provided in order to size the recess 1d.

The heat treatment step TT2 comprises, for example, a temperature holding stage at approximately 1050° C., in particular between 1000° C. and 1200° C., and can possibly occur between these different steps or substeps of the second phase of machining P2.

According to the second embodiment of the process, a heat treatment step TT1, comprising a temperature holding stage at approximately 1050° C., in particular between 1000° C. and 1200° C., can occur between the second and third phases P2, P3. In the first embodiment of the process, this step does not exist, but the first step TT1 comprising a temperature holding stage higher than 1100° C., in particular of between 1600° C. and 2000° C., is implemented. The first stress-relieving heat treatment step TT1′ can in particular be carried out:
at a temperature higher than 1600° C., and/or
at a temperature lower than 2000° C. or lower than 1950° C. or lower than 1800° C. or lower than 1750° C.

Irrespective of the embodiment or the variant, the third phase of finishing P3 can comprise various steps of brushing or polishing, whether it be chemical polishing or mechanical polishing. By way of example, this third phase can comprise a first step of brushing E31 intended to round off the edges of the bevels or bevelling. Various steps E32 of brushing or polishing can be provided to obtain the desired surface finishes for each of the surfaces of the glass. They may be steps of mechanical polishing or mechanical brushing or chemical brushing.

According to the second embodiment of the process, a heat treatment step TT1′, comprising in particular a temperature holding stage of between 1600° C. and 2000° C., can occur between two steps E31 and E32.

Irrespective of the embodiment or the variant, the manufacturing process advantageously makes it possible to produce a sapphire glass, in particular an uncolored sapphire glass, i.e. a glass which does not undergo a step exclusively dedicated to coloring it, as the experimental studies conducted by the Applicant have shown. Furthermore, irrespective of the embodiment or the variant, the process relates to any uncolored sapphire glass, irrespective of its crystallographic orientation (A or C) and irrespective of the process used to obtain it beforehand (Verneuil, EFG or Kyropoulos process). The orientation of the sapphire may be of type A, i.e. the optical axis is in the plane of the glass or can be spaced away by up to 15° from the plane of the glass. To implement a Verneuil process, such a sapphire orientation is preferred. As an alternative, the orientation of the sapphire may be of type C, i.e. the optical axis is normal or substantially normal to the plane of the glass. For such a sapphire orientation, the Kyropoulos and EFG growth processes are preferred.

Irrespective of the embodiment or the variant, the glass is preferably cylindrical or circular, but the process can be applied to any other glass geometry, such as a parallelepipedal or rectangular glass.

The manufacturing process is particularly indicated for obtaining a recessed glass with optimized mechanical characteristics.

Irrespective of the embodiment or the variant, one or several or all of the stress-relieving heat treatment steps can comprise a holding stage with a duration of several hours, for example between 2 hours and 15 hours, typically 5 hours.

Irrespective of the embodiment or the variant, one or several or all of the stress-relieving heat treatment steps can be carried out under a controlled atmosphere, in particular:
under vacuum, or
under a neutral or inert gas, or
under a reducing atmosphere, using for example a reducing gas such as an H2 -N2 mixture, or using for example a neutral or inert gas combined with graphite heating elements which will produce carbon monoxide, or
under an oxidizing atmosphere, for example under air.

As indicated above, the studies carried out by the Applicant have shown that the stress-relieving heat treatment step(s) enhance the mechanical properties of the glasses.

The embodiments and the variants of the process to which the invention relates, and in particular the processes described above, can make it possible to produce timepiece elements 100 like those described in more detail below. These timepiece elements 100 can also be obtained by any other process.

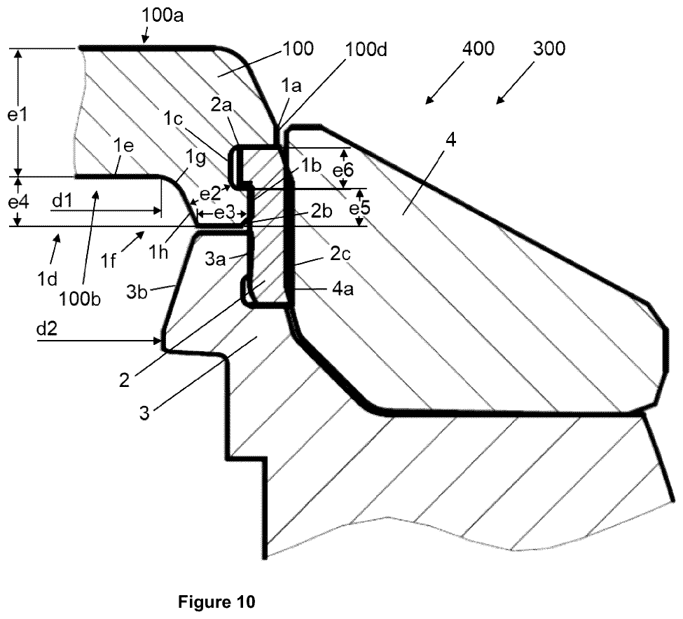

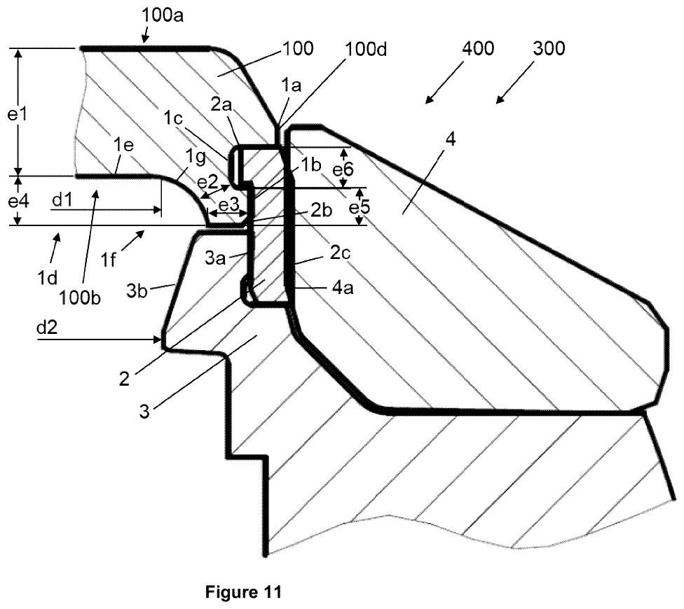

In the embodiments described in more detail below with reference to FIGS. 10 and 11, the watch case 400 comprises a glass 100, a seal 2, a middle 3 and a bezel 4. The glass 100 is machined from a slab which is preferably made of a hard material such as tempered glass or, advantageously, sapphire or more generally a transparent ceramic. The glass comprises:
an outer face 100a intended to be in contact with the external environment,
an inner face 100b intended to be in contact with the inner volume of the timepiece case, and
a lateral edge 100d connecting the outer face and the inner face.

The lateral edge 100d comprises a slot 1c. The inner face comprises a recess 1d such that the edge 100d comprises a skirt 1f. The glass 100 thus has a skirt 1f which is located at the interface of the recess 1d and the lateral edge 100d of the glass. The recess 1d can have a recess bottom 1e with a planar, substantially planar, concave or substantially concave geometry. Preferably, from the recess bottom 1e, the recess 1d has a flared portion 1h, in particular a substantially frustoconical flared portion, at the skirt 1f. In other words, the portion 1h preferably comprises substantially inclined sidewalls in relation to the recess bottom 1e. The transition between the recess bottom 1e and the portion 1h has a fillet 1g. More preferably, the recess bottom 1e of the recess has a dimension, in particular a diameter d1, measured at the base of the fillet 1g, which is substantially equal to or greater than the aperture dimension, in particular diameter, d2 in the middle 3, in particular at a flange 3b. In other words, the largest surface area inscribed within the aperture dimension d2 is preferably smaller than the surface area of the recess bottom 1e of the recess. In other words, the largest surface area inscribed within the aperture dimension d2 can be inscribed onto the surface area formed by the recess bottom 1e or onto a projection of the surface area formed by this recess bottom 1e onto a plane parallel to one and/or the other of these areas. This makes it possible to optimize the readability of the dial and the set of hands, by avoiding any visual distortion of the dial liable to be caused by the geometry of the skirt 1f through the glass 100.

If the flange is held by the dial, the aperture diameter d2 corresponds to the inside diameter at the base of the dial flange.

As an alternative, the portion 1h can have substantially straight or perpendicular sidewalls in relation to the recess bottom 1e, in particular substantially cylindrical sidewalls. As another alternative, it is possible for the recess 1d to not comprise a portion 1h, but only a fillet 1g. Preferably, a projection of the surface area formed by this fillet 1g onto a plane parallel to the dial is inscribed in the projection of the surface area of the flange 3b onto this same plane or outside the projection of the surface area of the flange 3b onto this same plane such that the projection along the axis A1 of the surface area of the fillet 1g does not cover the visible zone of the dial.

In the embodiment described below in greater detail with reference to FIG. 10, the glass 100 comprises, on the lateral edge 100d, two portions of different sizes, in particular different diameters. A portion 1a of large size, in particular of large diameter, is arranged on the outer face of the watch case and a portion 1b, of smaller size, in particular of smaller diameter, is arranged on the inner face of the case once the glass has been mounted on the case. A groove 1c or a slot 1c, in particular an annular groove 1c, separates said portions 1a and 1b.

The seal 2 has a shape adapted to the periphery of the glass 100, in particular an annular shape. The longitudinal section of the seal in relation to the axis A1 comprises a zone extending toward the axis A1. This portion forms a projection 2a. The seal 2 comprises an inner surface 2b intended to cooperate with the glass 100 and the middle 3, and an outer surface 2c intended to cooperate with the bezel 4. More particularly, the inner surface 2b cooperates by driving-in with the portion 1b of the glass 100 and with an outer lateral surface 3a of the middle 3 which is located substantially at the same level as the flange 3b of the middle 3. The outer surface 2c cooperates by driving-in with an inner lateral surface 4a of the bezel 4. Thus, the lateral edge 100d comprises:
on a first side of the annular slot 1c, the first portion 1b intended to cooperate with the seal 2, and
on a second side of the annular slot 1c, the second portion 1a, of greater size, in particular greater diameter, than the first portion 1b.

The driving-in of the bezel 4 against the seal 2 makes it possible to radially compress the latter against the glass 100 and the middle 3, thus ensuring that the assembly has optimum strength and water resistance.

Preferably, the size of the portion 1a, in particular the diameter of the portion 1a, of the glass is very slightly smaller than the size of the outer surface 2c of the seal, in particular the diameter of the outer surface 2c of the seal, such that the latter is largely concealed or covered by the glass (as seen perpendicularly to the glass from the outside). This results in a reduced gap between the glass 100 and the bezel 4, between the portion 1a and the inner lateral surface 4a. As a result, the bulk of the bezel 4 is advantageously reduced, since it is not necessary for the bezel to pass above (along an axis parallel to the thickness of the case) the seal 2 to hide it.

Moreover, the seal 2 comprises the projection 2a, in particular an annular projection 2a, intended to be placed within the groove or the slot 1c in the glass. This projection 2a advantageously extends radially toward the inside in relation to the axis A1. This shaping advantageously makes it possible to anchor the glass 100 against the seal 2 and to thus ensure better driving-out strength of the latter, for the same given radial force against the skirt 1f, for example when the inside of the case is subjected to a higher pressure than the outside. The glass 100 is thus advantageously held by the seal 2 by friction and by anchoring or constraint. Thus, the slot 1c cooperates with the projection 2a of the seal 2 so as to anchor the glass 100, in particular to the bezel 4 and/or to the middle 3.

The optimized strength made possible by the anchoring of the glass 100 on the seal 2 advantageously makes it possible to obtain a very small residual wall thickness e2 between the groove or the slot 1c and the recess 1d, and a very small radius of the fillet 1g, without compromising the mechanical strength of the glass 100. Specifically, for the same driving-out strength of the glass, the anchoring makes it possible to limit the radial forces associated with the assembly, and thus makes it possible to minimize this residual wall thickness e2 and the minimum radius of the fillet 1g. For example, this fillet 1g may be of the order of only 0.1 mm, and the thickness e2 may be of the order of only 0.4 mm. The portion 1h is preferably flared so as to have substantially inclined sidewalls in relation to the recess bottom 1e, in particular a frustoconical surface portion, for limiting the stress concentrations at the skirt 1f. These dimensions can in particular be achieved for watch cases which are sized to resist accidental shocks according to the ISO 1413 and NIHS 91-10 standards and to be water resistant down to at least 100 meters, i.e. at a pressure of at least 10 bar. Consequently, the skirt 1f can also have a cross section with a residual wall thickness e3, measured between the portion 1b and the recess 1d, which is advantageously smaller than the thickness e1 of the glass, measured between the outer face of the glass and the bottom of the recess 1d, i.e. e3/e1<1.

In addition, by virtue of the anchoring described above, the recess 1d makes it possible to further reduce the bulk of the watch case. Specifically, this solution advantageously makes it possible to obtain a minimum thickness e1 in the center of the glass 100, defined by material strength calculations, without modifying the attractive appearance of the watch case on the glass side. As a result, the set of hands of the movement can advantageously be located, at least in part, within the recess 1d. This therefore makes it possible to offset the movement on the glass side and to even further reduce the thickness of the watch case on the back side.

Advantageously, the anchoring and water resistance of the glass 100 are provided so as to be offset as far as possible toward the inside of the case, so that also the assembly of the bezel 4 is inwardly offset and the thickness of the watch case is reduced. As a result, the material thickness e5 between the end of the skirt 1f at the portion 1b, and the groove or the slot 1c is advantageously smaller than the depth e4 of the recess 1d. Consequently, the ratio of e 5 to e4 can advantageously be less than 1, i.e. e5/e4<1.

In the embodiment illustrated by FIG. 10, the glass 100 is sized to withstand immersion in water to a depth of 100 m, with a thickness e1 of 1.3 mm and a recess 1d with a depth e4 of 0.5 mm. The residual wall thickness between the groove or the slot 1c and the recess 1d has a thickness e2 of 0.49 mm. The thickness e3 of the cross section of the skirt 1f is 0.55 mm with a fillet 1g of a radius of 0.3 mm. The ratio of e3 to e1 is equal to 0.42. The thickness e5 is 0.38 mm. Therefore, the ratio of e5 to e4 is equal to 0.76.

In the embodiment illustrated by FIG. 11, the glass 100 is sized to withstand immersion in water to a depth of 100 m, with a glass thickness e1 of 1.3 mm and a recess 1d with a depth e4 of 0.5 mm. The residual wall thickness between the groove or the slot 1c and the recess 1d has a thickness e2 of 0.390 mm. The thickness e3 of the cross section of the skirt 1f is 0.45 mm with a fillet 1g of a radius of 0.6 mm. The ratio of e3 to e1 is equal to 0.35. The thickness e5 is 0.38 mm. Therefore, the ratio of e5 to e4 is equal to 0.76. By contrast to the embodiment illustrated by FIG. 10, the skirt 1f does not comprise a frustoconical portion 1h.

The two embodiments described comprise a glass with a planar outer surface. However, irrespective of the embodiment or the variant, the solution is also applicable to a glass having a domed outer surface. The same applies to the bottom of the recess which can also have a concave or domed surface.

Irrespective of the embodiment or the variant, the fillet 1g can coincide with the recess bottom 1e of the recess 1d which then comprises a concave or substantially concave surface which extends from the center to the edge of the glass 100.

Irrespective of the embodiment or the variant, preferably, the seal 2 is made of:
nylon or polyamide, such as polyamide 6 or 6.6 or a Zytel® or a Grilamid®, or
thermoplastic elastomer or thermoplastic elastomer copolyester such as Hytrel®.

The timepiece element 100 described with reference to FIGS. 1, 3, 10 and 11 is a glass intended to allow a dial, or more generally any display device of a timepiece, to be seen through it. However, irrespective of the embodiment or the variant, the timepiece element 100 can be a back glass, i.e. a glass which allows a timepiece movement or any mechanism of a timepiece movement to be seen through it. This glass can be mounted directly on a middle or on any intermediate element capable of being mounted on the middle. As a result, a back glass can be mounted on a back which takes for example the form of an annular element that can be mounted on the middle.

The timepiece element 100 described with reference to FIGS. 1, 3, 10 and 11 is circular. However, irrespective of the embodiment or the variant, the timepiece element 100 can be non-circular; it can in particular take the form of a barrel or have a substantially rectangular shape or a substantially square shape. As a result, the slot 1c has a similar circular or non-circular geometry.

Irrespective of the embodiment or the variant, the timepiece element 100 can comprise a slot 1c all around its periphery or it can comprise a slot 1c around several portions angularly limited in extent about the axis A1, i.e. several cavities. These portions or cavities are preferably:
distributed evenly around the axis A1, and/or
capable of cooperating with as many internal projections of the seal 2.

Irrespective of the embodiment or the variant, the timepiece element 100 is preferably sized to withstand a pressure of at least 10 bar applied to the outer face (water resistance down to 100 m), in particular 20 bar (water resistance down to 200 m) or 30 bar (water resistance down to 300 m).

Irrespective of the embodiment or the variant, the first thickness e1 measured between the outer face and the bottom of the recess can be comprised between 1 mm and 1.5 mm or typically amount to approximately 1.3 mm.

Irrespective of the embodiment or the variant, the second thickness e2 measured between the bottom of the slot and a sidewall of the recess can be comprised between 0.35 mm and 0.5 mm.

Irrespective of the embodiment or the variant, the third thickness e3 of the skirt measured between the portion 1b and the recess 1d can be comprised between 0.4 mm and 0.6 mm.

Irrespective of the embodiment or the variant, the ratio of the third thickness e3 to the first thickness e1 can be less than 1, or even comprised between 0.3 and 0.5, or typically amount to 0.35 or 0.42.

Irrespective of the embodiment or the variant, the depth e4 of the recess 1d can be comprised between 0.2 mm and 0.6 mm.

Irrespective of the embodiment or the variant, the thickness e5 of the first portion 1b can be comprised between 0.3 mm and 0.4 mm, or typically amount to 0.38 mm.

Irrespective of the embodiment or the variant, the ratio of the thickness e5 to the depth e4 of the recess 1d can be less than 1, or even comprised between 0.7 and 0.8, or typically amount to 0.76. However, in the specific instance in which the depth e4 is particularly small, around 0.2 or 0.3, this thickness ratio can be greater than 1.

Irrespective of the embodiment or the variant, the fillet 1g can have a radius of between 0.1 mm and 0.7 mm, or typically amounting to 0.3 mm or 0.6 mm.

Irrespective of the embodiment or the variant, the seal 2 is preferably arranged between the bezel and the timepiece element 100.

Irrespective of the embodiment or the variant, the width e6 of the slot, measured parallel to the axis A1, can be comprised between 0.2 mm and 0.5 mm.

By virtue of the solutions which are the aims of the invention, by contrast to the prior-art solutions, it is possible to produce a watch case of reduced thickness with, for example, a seal hidden by a glass or a bezel which overhangs it, and without visual distortion.

The processes to which the invention relates afford glasses which are resistant to shocks, in particular have strength characteristics superior to the very high requirements made by the applicant. This makes it possible to produce a recessed and thinned sapphire glass.

1. A process for manufacturing a sapphire timepiece element(100), the process comprising:
machining phase, followed by
a finishing phase,
the process further comprising performing a first stress-relieving heat treatment, the first stress-relieving heat treatment comprising performing a first holding stage at a first temperature higher than 1100° C. after the machining phase.

2. The process according to claim 1, wherein
the first temperature is higher than 1600° C., and/or
the first temperature is lower than 2000° C.

3. The process according to claim 1, wherein the first stress-relieving heat treatment takes place between the machining and finishing phases.

4. The process according to claim 1, wherein the first stress-relieving heat treatment takes place between two successive polishing stages of the finishing phase.

5. The process according to claim 1, wherein the process further comprises performing a second stress-relieving heat treatment, the second stress-relieving heat treatment comprising performing a holding stage at a temperature in a range of from 1000° C. to 1200° C.

6. The process according to claim 5, wherein the second stress-relieving heat treatment takes place between the machining and finishing phases.

7. The process according to claim 5, wherein the process further comprises performing a third stress-relieving heat treatment, comprising performing a holding stage at a temperature in a range of from 1000° C. to 1200° C. wherein the third stress-relieving heat treatment takes place between two successive machining stages of the machining phase.

8. The process according to claim 7, wherein the process comprises:
performing a preparation phase prior to the machining, and
performing a fourth stress-relieving heat treatment, comprising a holding stage at a temperature in a range of from 1000° C. to 1200° C., wherein the fourth stress-relieving heat treatment takes place between the preparation phase and the machining.

9. The process according to claim 1, wherein the first holding stage at the first temperature has a duration in a range of from 2 hours to 15 hours.

10. The process according to claim 8, wherein one, a plurality, or all of the second, third and fourth stress-relieving heat treatments comprises or comprise a holding stage at a temperature of approximately 1050° C., the holding stage having a duration in a range of from 2 hours to 15 hours.

11. The process according to claim 8, wherein one, a plurality, or all of the first, second, third and fourth stress-relieving heat treatments are carried out under a controlled atmosphere.

12. The process according to claim 1, wherein
the timepiece element is a glass and the machining comprises making a recess in the glass, and/or
the timepiece element is made of colorless sapphire or uncolored sapphire.

13. The process according to claim 1, wherein the timepiece element is an external-parts element or a timepiece-movement element.

14. A sapphire timepiece element obtained by implementing the process according to claim 1.

15. A timepiece case comprising a sapphire timepiece element according to claim 1.

16. A timepiece comprising a sapphire timepiece element according to claim 1.

17. The process according to claim 2, wherein the first temperature is lower than 1750° C.

18. The process according to claim 5, wherein the holding stage is performed at a temperature of approximately 1050° C..

19. The process according to claim 7, wherein the holding stage of the third stress-relieving heat treatment is performed at a temperature of approximately 1050° C..

20. The process according to claim 8, wherein the holding stage of the fourth stress-relieving heat treatment is performed at a temperature of approximately 1050° C..
